(19) United States
(12) Patent Application Publication
(10) Pub. No.: US 2025/0079304 A1
(43) Pub. Date: Mar. 6, 2025

(54) SEMICONDUCTOR GAP FILL AND PLANARIZATION

(71) Applicant: Taiwan Semiconductor Manufacturing Co., Ltd., Hsinchu (TW)

(72) Inventors: Liang-Shiuan PENG, Taipei City (TW); Chih-Hung LU, Hsinchu County (TW)

(73) Assignee: Taiwan Semiconductor Manufacturing Co., Ltd., Hsinchu (TW)

(21) Appl. No.: 18/457,975

(22) Filed: Aug. 29, 2023

(51) Int. Cl. H01L 23/528; H01L 21/768

(52) U.S. Cl. CPC H01L 23/5283; H01L 21/76837

(57) ABSTRACT

The present disclosure describes a semiconductor structure that can provide improved gap fill. The semiconductor structure can include conductive features disposed on a first layer separated by a distance and a layer disposed over the conductive features and the first layer. The layer can include triangular-shaped peaks above each conductive feature in the conductive features and valley regions above the first layer.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as a connection structure. Such scaling down has increased the complexity of semiconductor manufacturing processes and increased the difficulty of defects control in the semiconductor devices.

### BRIEF DESCRIPTION OF THE DRAWINGS

Aspects of the present disclosure are best understood from the following detailed description when read with the accompanying figures.

FIGS. 1-4 are cross-sectional views of a semiconductor device having improved gap fill, in accordance with some embodiments.

FIGS. 5-7 are flow diagrams of methods for improving semiconductor device feature gap fill, in accordance with some embodiments.

FIGS. 8-22 are cross-sectional views of a semiconductor device having improved gap fill, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, 2%, ±3%, ±4%, 5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, semiconductor devices can include several device features that extend upwardly from a substrate and/or a first layer (for example, a conductive first layer, metallic interconnects, transistor gate structures, mandrels, connection pads, a conductive material, or the like) that create a surface topography having various feature elevations. In some embodiments, a film can be deposited over the device features as layer-by-layer fabrication progresses. In some embodiments, during film deposition over device features, the film can collect on the top of the device features and outwardly extend from the top of the device feature spaces. In some embodiments where device features are adjacent to each other, the outward growth of one device feature can extend and contact the outward growth of another device feature. In some embodiments, this undesirable contact from two adjacent device features can create a pinch point, thus sealing a gap between the device features. Such sealing can prevent filling of the gap between the device features. In some embodiments, it is desirable to fill the gaps for various reasons, such as to prevent electrical communication between the features, to prevent air and/or oxygen from being trapped in the gaps, to prevent creating a vacuum in the gap that can cause damage to the device when removed from a vacuum process, or to facilitate downstream processing, including chemical mechanical planarization.

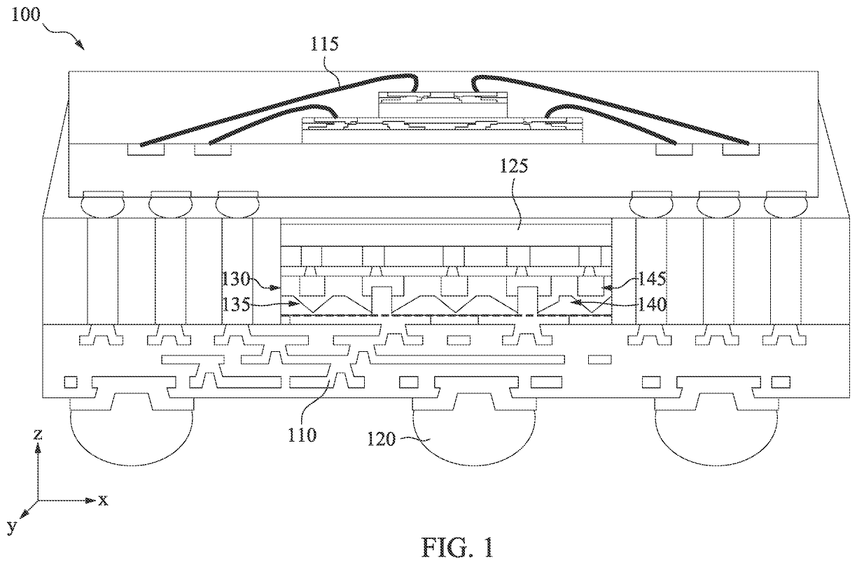

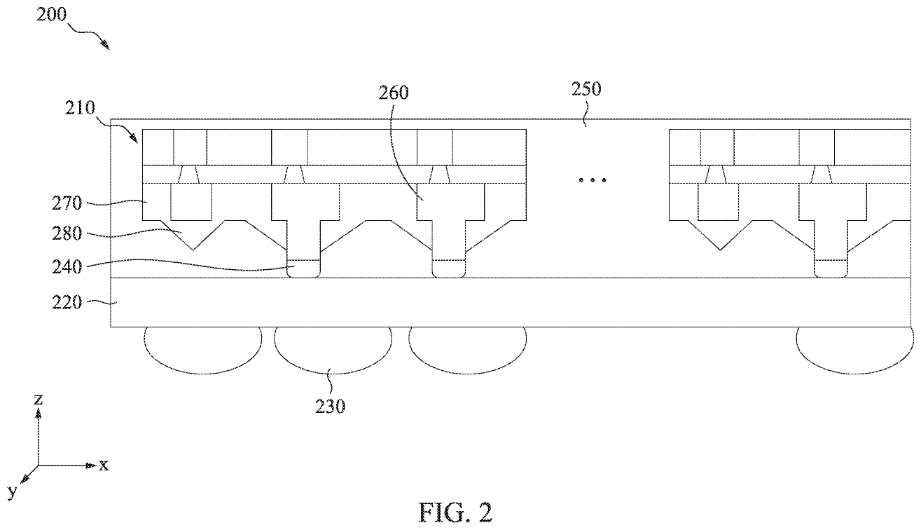

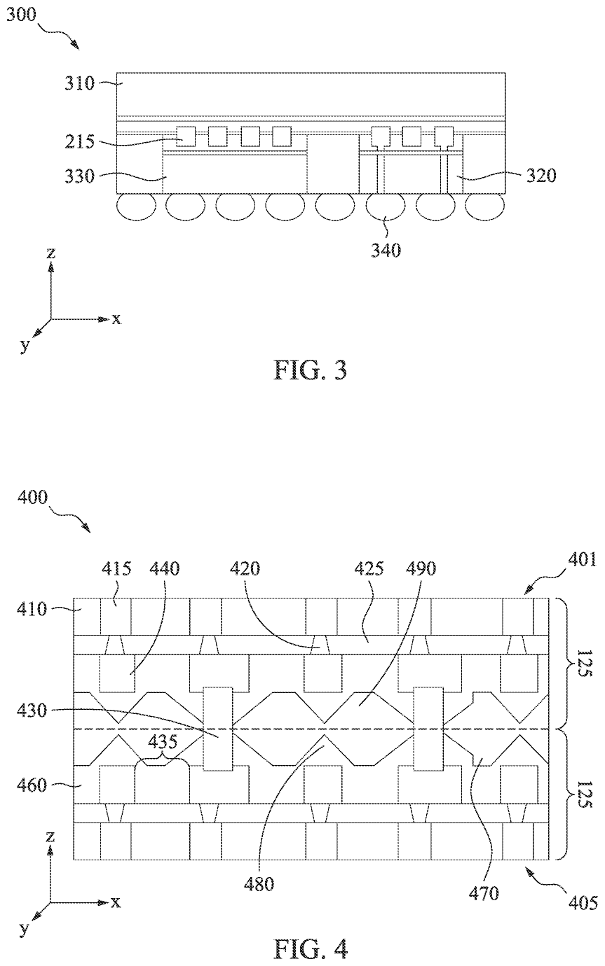

FIG. 1 illustrates a cross-sectional view of a semiconductor package device 100 having a semiconductor device 125 that can have a material film topography exhibiting an improved gap fill, according to some embodiments. FIG. 2 is a cross-sectional view of a semiconductor device 210 having the improved gap fill and connected to a substrate 220, according to some embodiments. FIG. 3 is a cross-sectional view showing optional chip bonding configurations, according to some embodiments. FIG. 4 is a cross sectional view showing two semiconductor devices connected together having the improved gap fill, according to some embodiments. For explanation purposes, reference will be made to FIG. 4 throughout this disclosure.

Referring to FIG. 1, a semiconductor package device 100 can include a plurality of layers (for example, a substrate, dielectric layers, fill layers, capping layers, or the like), interconnects 110, wire bonds 115, solder bumps 120, and semiconductor devices 125, according to some embodiments of the present disclosure. The semiconductor package device 100 can include the semiconductor device 125 in any desired configuration, for example, disposed on a substrate and electrically coupled to one or more of the interconnects 110. In some embodiments, the semiconductor device 125 can include a material film topography exhibiting an improved gap fill. A first film 130 can be etched to provide triangular-shaped structures 135 enabling a second film 140 to fill in between conductive features 145.

FIG. 2 shows a cross section of a portion of a semiconductor package device 200, according to some embodiments of the present disclosure. The semiconductor device 210 can be electrically coupled to a substrate 220 (having solder bumps 230) via interconnect solder bumps 240. In some embodiments, the semiconductor device 210 can be encapsulated with an underfill (or molding) 250. In some embodiments, the underfill or molding 250 can be a dielectric material (for example, an amorphous or crystalline high-k material such as a polymer, a metal oxide, an alloy oxide, or any suitable high-k material). In some embodiments, the semiconductor device 210 can include the material film topography exhibiting an improved gap fill as previously noted. A material film 270 can be etched to provide triangular-shaped structures 280 enabling the underfill or molding 250 to fill in between conductive features 260.

FIG. 3 is an illustration showing placement of the semiconductor device 125 in a chip bonded structure 300, according to some embodiments of the present disclosure. Any one of Chip 1 310, Chip 2 320, or Chip 3 330 can be the semiconductor device 125. As shown in FIG. 3, the semiconductor device 125 can be bonded by their respective interconnect solder bumps 215. In some embodiments, the chip-bonded structure 300 can have solder bumps 340 enabling further chip bonding.

FIG. 4 is an illustration showing two semiconductor devices 125 bonded together in a three dimensional integrated circuit package structure 400, according to some embodiments of the present disclosure. As shown in FIG. 4, a first semiconductor device chip 400 can be electrically coupled to a second semiconductor device chip 405 using interconnects 430. The interconnects 430 are electrically coupled to conductive features 440 (for example, a metal interconnect, a metal feature, or a mandrel). The conductive features 440 can further be electrically coupled to metal features 415 disposed on or within a substrate 410 using vias 420 disposed in a first layer (for example, an interlayer dielectric) 425. A second layer 460 and a third layer 470 can be a high-k dielectric material (for example, a passivation layer, an interlayer dielectric, or the like) disposed over and around the conductive features 440. In some embodiments, the two semiconductor devices 125 can include an improved gap fill topography. For example, the second layer 460 can be etched to form triangular-shaped peaks 480 above the conductive features 440. In some embodiments, the etching can also form valley regions 490 above the gaps 435. Also, in some embodiments, the third layer 470 can fill in the valley regions 490 and can be optionally planarized for downstream processing.

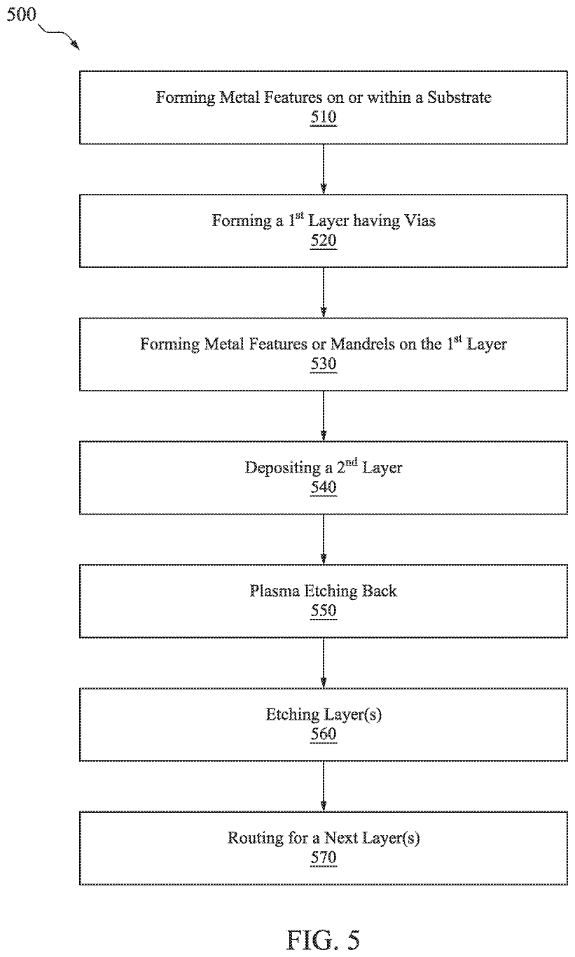

In some embodiments of the present disclosure, a method of making a semiconductor device with improved material gap fill is described. In some embodiments of the present disclosure, FIG. 5 is a flow chart illustrating an improved gap fill method 500. For illustrative purposes, the operations of method 500 will be described with reference to FIGS. 4 and 8-12. The operations of method 500 can be performed in a different order, repeated (either immediately or further downstream), or not performed depending on specific applications. Further, it is understood that additional operations can be provided before, during, and after method 500, and that other operations may only be briefly described herein.

Referring to FIG. 5, the method 500 begins with operation 510 and the process of forming metal features on a first layer (for example, a substrate, an interlayer dielectric, a dummy fill, a gate structure, or the like). For example, as shown in FIG. 4, a substrate 410 can have metal features 415 formed within the substrate. For illustrative purposes, the entire thickness of the substrate 410 is not shown, thus the metal features 415 are formed on or within a surface of the substrate 410 and exposed for connection to interlayer interconnects.

In some embodiments, at operation 520, the interlayer interconnects are provided by forming vias 420 in a first layer 425. In some embodiments, at operation 530, conductive features 440 (for example, metal features or mandrels) can be formed above the vias 420 to provide electrical connection to the metal features 415 on or within the substrate 410. After forming the conductive features 440, the method can include, at operation 540, depositing the second layer 460 over (for example, covering) the conductive features 440 and gaps 435 between the conductive features 440. In some embodiments, the second layer 460 can be a dielectric material. For example, the second layer 460 can be any one of silicon dioxide, silicon nitride, a polymer (for example, polyimide), or combinations thereof.

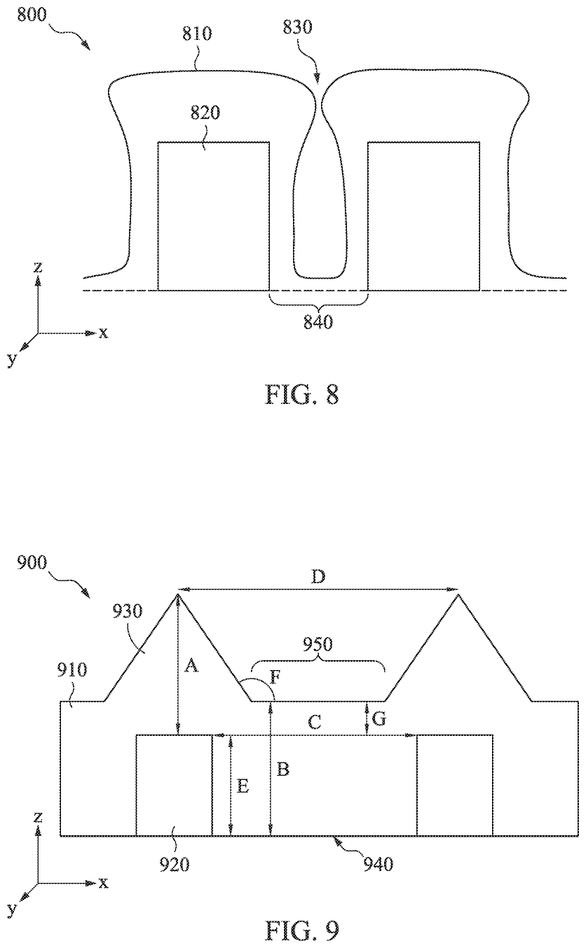

In some embodiments, depositing the second layer can contribute to pinch point formation and sealing gaps 840 corresponding to the gap 435 depicted in FIG. 4 between the conductive features 820 corresponding to the conductive features 440 depicted in FIG. 4 as illustrated in FIG. 8. As shown in FIG. 8, in some embodiments when depositing a second layer 810 corresponding to the second layer 460 depicted in FIG. 4 over a conductive feature 820, there can be upward and outward growth of the second layer 810 being deposited over the conductive features 820 that can form a pinch point 830 over the gap 840. Accordingly, in some embodiments the pinch point 830 can prevent material fill in the gap 840 corresponding to the gap 435 depicted in FIG. 4. Depositing the second layer 810 can be performed using any plasma enhanced material deposition process, for example, plasma enhanced chemical vapor deposition (PECVD), sputtering, plasma enhanced atomic layer deposition (PEALD), or the like. Referring to FIG. 5, at operation 550, in some embodiments, the plasma enhanced material deposition can be stopped and the plasma can be used to etch back at least a portion of the deposited second layer 810.

FIG. 9 is an illustration of an embodiment providing optional semiconductor device structural dimensions extending along the x-axis and the z-axis as presented in the figure. The dimensions are provided as minimum-maximum value ranges with corresponding intermediate values provided to convey embodiments directed to achieving the improved gap fill as described. For example, dimension C provides a distance for the valley region 950 extending along the x-axis. In some embodiments, dimensions A and B describe the film thickness (or, for example, the film height) along the z-axis. For example, dimension A is greater than dimension E such that the base of the triangular-shaped peak 930 is wider along the x-axis than the width of the conductive feature 920. Dimension B is greater than dimension E such that the material layer 910 covers the conductive feature 920. Dimension D and angle F provide a valley region 950 that is amenable to material fill to alleviate the pinch point 830 shown in FIG. 8. Accordingly, the values and value ranges provided below are provided as critical dimensions to arrive at covering the conductive features 920 with the improved gap fill.

As shown in FIG. 9, in some embodiments the plasma etching back operation 550 can provide a film surface profile 900 having peaks 930 corresponding to the triangular-shaped peaks 480 depicted in FIG. 4 disposed above the conductive features 920 corresponding to the conductive features 440 depicted in FIG. 4. In some embodiments, the conductive features 920 can have a height E ranging from about 0.5 microns (μm) to about 6 μm along the z-axis. For example, the conductive feature height E can be about 0.5 μm, about 0.75 μm, about 1 μm, about 1.5 μm, about 2 μm, about 2.5 μm, about 3 μm, about 3.5 μm, about 4 μm, about 4.5 μm, about 5 μm, about 5.5 μm, or about 6 μm. In some embodiments, the conductive features 920 can have a width ranging from about 1 μm to about 5 μm (for example, about 1 μm, about 2 μm, about 3 μm, about 4 μm, or about 5 μm).

In some embodiments, the conductive features 920 can be separated by a center-to-center distance D along the x-axis. For example, the conductive features 920 can be separated by a center to center distance ranging from about 1.5 μm (for example, about 1.4 μm, about 1.6 μm, about 1.3 μm, about 1.7 μm, about 1.25 μm, or about 1.75 μm) to about 6.5 μm. Likewise, in some embodiments the conductive features 920 can be separated by a feature to feature distance C ranging from about 1 μm to about 5 μm (for example, the conductive features 920 can be separated by a feature to feature distance C of about 1 μm, about 1.5 μm, about 2 μm, about 2.5 μm, about 3 μm, about 3.5 μm, about 4 μm, about 4.5 μm, or about 5 μm). In some embodiments, the feature-to-feature distance is sufficiently wide to deposit a material between conductive features.

In some embodiments, after depositing the material layer 910 corresponding to the second layer 460 depicted in FIG. 4, the plasma etching back operation 550 can be performed using an oxygen plasma. The plasma etching back time can range from about 20 seconds (s) to about 500 s. For example, the plasma etching back time can be about 20 s, about 30 s, about 40 s, about 50 s, about 60 s, about 90 s, about 120 s, about 150 s, about 180 s, about 210 s, about 240 s, about 270 s, about 300 s, about 330 s, about 360 s, about 390 s, about 420 s, about 450 s, about 480 s, or about 500 s. In some embodiments, the chamber pressure during the plasma etching back can range from about 0.5 milliTorr (mT) to about 20 mT. For example, the chamber pressure during plasma etching back can be about 0.5 mT, about 0.75 mT, about 1 mT, about 5 mT, about 10 mT, about 15 mT, or about 20 mT. In some embodiments, the plasma source radio frequency (RF) can range from about 500 Watts (W) to about 11 kiloWatts (kW). For example, the plasma source RF can be about 500 W, about 750 W, about 1 kW, about 2 kW, about 3 kW, about 4 kW, about 5 kW, about 6 kW, about 7 kW, about 8 kW, about 9 kW, about 10 kW, or about 11 kW. Additionally, in some embodiments the bias RF (in other words, the RF applied to the target stage to attract excited plasma species to the target, in this case, the material layer 910) can range from about 1 kW to about 100 kW (for example, about 1 kW, about 10 kW, about 20 kW, about 30 kW, about 40 kW, about 50 kW, about 60 kW, about 70 kW, about 80 kW, about 90 kW, or about 100 kW).

In some embodiments, performing the plasma etching back operation 550 according to the parameters recited above can provide the film surface profile 900 shown in FIG. 9. As shown in FIG. 9, the plasma etching back can provide triangular-shaped peaks 930 corresponding to the triangular-shaped peaks 480 depicted in FIG. 4 over the conductive features 920 corresponding to the conductive features 440 depicted in FIG. 4 by removing the outward film growth that can appear during the layer deposition operation 540 (see FIG. 8) and the resulting pinch point 830. Further, in some embodiments, the plasma etching back can provide valley regions 950 corresponding to the valley regions 490 depicted in FIG. 4 between the peaks 930. In some embodiments, the top of the valley regions 950 disposed between the peaks 930 can be substantially flat. In some embodiments, the material layer 910 corresponding to the second layer 460 depicted in FIG. 4 can have a resulting base film thickness B ranging from about 0.6 μm to about 12 μm along the z-axis. For example, the material layer 910 can have a thickness from the first layer 940 corresponding to the first layer 425 depicted in FIG. 4 to the top of the material layer 910 after the plasma etching back of about 0.6 μm, about 0.7 μm, about 0.8 μm, about 0.9 μm, about 1 μm, about 2 μm, about 3 μm, about 4 μm, about 5 μm, about 6 μm, about 7 μm, about 8 μm, about 9 μm, about 10 μm, about 11 μm, or about 12 μm. Likewise, in some embodiments, the thickness of the peak A above the conductive feature 920 can range from about 0.5 μm to about 10 μm. For example, the peak thickness above the conductive feature 920 can be about 0.5 μm, 0.6 μm, 0.7 μm, about 0.8 μm, about 0.9 μm, about 1 μm, about 2 μm, about 3 μm, about 4 μm, about 5 μm, about 6 μm, about 7 μm, about 8 μm, about 9 μm, or about 10 μm.

In some embodiments, after the plasma etching back operation 550 is performed, the thickness of the peak A can be less than the base film thickness B along the z-axis. In some embodiments, the base film thickness B can be greater than the height E of the conductive features 920. For example, the base film thickness B can be greater than the height E of the conductive feature 920 corresponding to the conductive features 440 depicted in FIG. 4 by the difference G (for example, B_{z-axis}−E_{z-axis}=G_{z-axis}). In some embodiments, the difference G between the height E of the conductive features 920 and the base film thickness B can range from about 0.1 μm to about 9 μm. For example, B-E can equal about 0.1 μm, about 0.2 μm, about 0.3 μm, about 0.4 μm, about 0.5 μm, 0.6 μm, 0.7 μm, about 0.8 μm, about 0.9 μm, about 1 μm, about 2 μm, about 3 μm, about 4 μm, about 5 μm, about 6 μm, about 7 μm, about 8 μm, or about 9 μm.

In some embodiments, the aspect ratio of the valley region 950 can range from about 5 to about 10, corresponding to an angle F ranging from about 900 to about 1500 between the triangular-shaped peak 930 (along the z-axis) and the x-axis. The aspect ratio can be a ratio of the depth and/or height of a feature to the width of the feature, for example, as depicted in FIG. 9, the aspect ratio is a ratio of values along the z-axis to values along the x-axis, or Z:X. For example, the valley region 950 aspect ratio (for example, a ratio between the height A and the valley region 950) can be about 5, about 6, about 7, about 8, about 9, or about 10. In some embodiments, angle F can be about 90°, 95°, 100°, 105°, 110°, 115°, 120°, 125°, 130°, 135°, 140°, 145°, or about 150°.

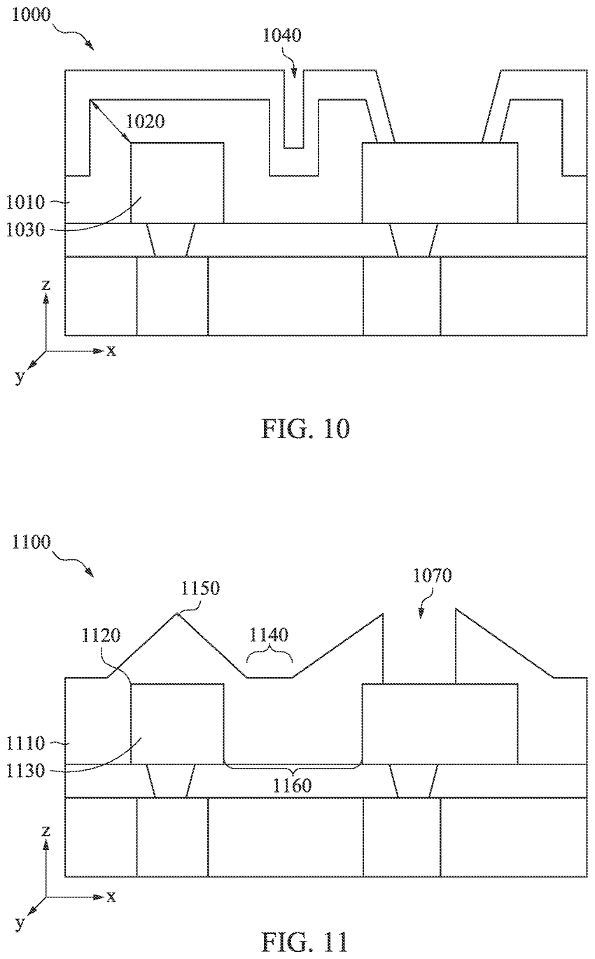

In some embodiments, FIG. 10 illustrates a film surface profile 1000 that can occur when the plasma etching back is not performed. Notably, in some embodiments the thickness of the material layer 1010 corresponding to the second layer 460 depicted in FIG. 4 at the top corner 1020 of the conductive feature 1030 corresponding to the conductive features 440 depicted in FIG. 4 can be susceptible to cracking, delamination, and poor thermal dissipation. Additionally, in some embodiments the material layer 1010 can include a low aspect ratio gap 1040 between the conductive features 1030. Such a low aspect ratio gap 1040 can be difficult to fill if desired.

As shown in FIG. 11, in some embodiments the film surface profile 1100 provided by the plasma etching back operation 550 can alleviate the problems illustrated in FIG. 10. In some embodiments, the plasma etched back material layer 1110 corresponding to the second layer 460 depicted in FIG. 4 can be contoured and thinner at the top corner 1120 of the conductive feature 1130. Additionally, the contour of the material layer 1110 can provide a valley region 1140 corresponding to the valley regions 490 depicted in FIG. 4 between the peaks 1150 corresponding to the triangular-shaped peaks 480 depicted in FIG. 4 disposed above the conductive features 1130 corresponding to the conductive features 440 depicted in FIG. 4 that can be amenable to filling the gap 1160 corresponding to the gap 435 depicted in FIG. 4 with a desired material.

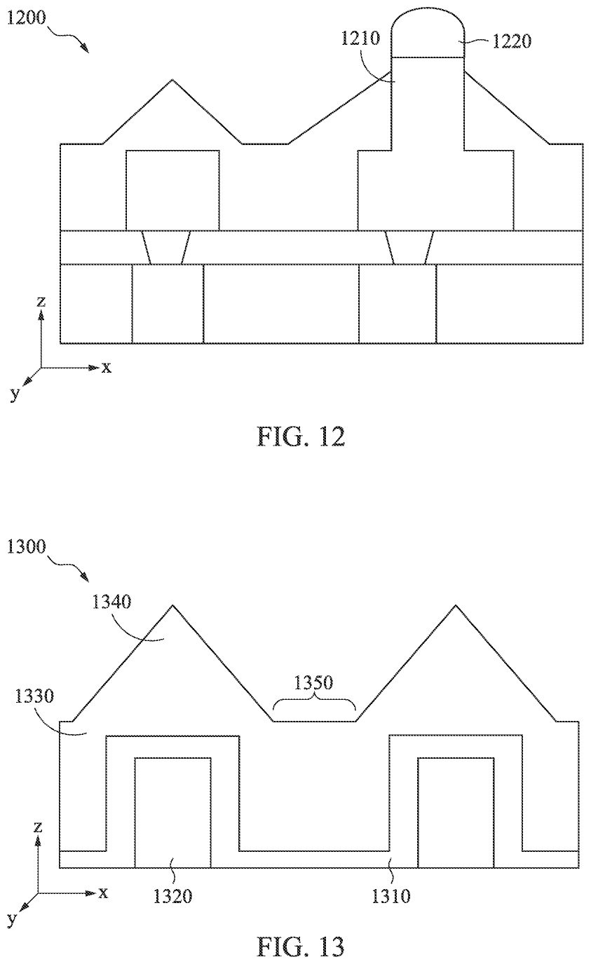

Referring to FIG. 5, in some embodiments, after the plasma etching back operation 550 is performed, the semiconductor device can be subjected to processing to provide an exposed conductive feature 1130 corresponding to the conductive features 440 depicted in FIG. 4. As shown in FIG. 11, at least a portion of the material layer 1110 corresponding to the second layer 460 depicted in FIG. 4 can be etched in operation 560 to provide an interconnect via 1170. In some embodiments, the next layer routing operation 570 can include metallization (for example, resistive evaporation, sputtering, or electrochemical plating). Referring to FIG. 12, metallization can be performed to provide the interconnect 1210 in the via 1170, corresponding to the interconnect 430 depicted in FIG. 4. Additionally, in some embodiments soldering can be performed to provide a solder bump 1220.

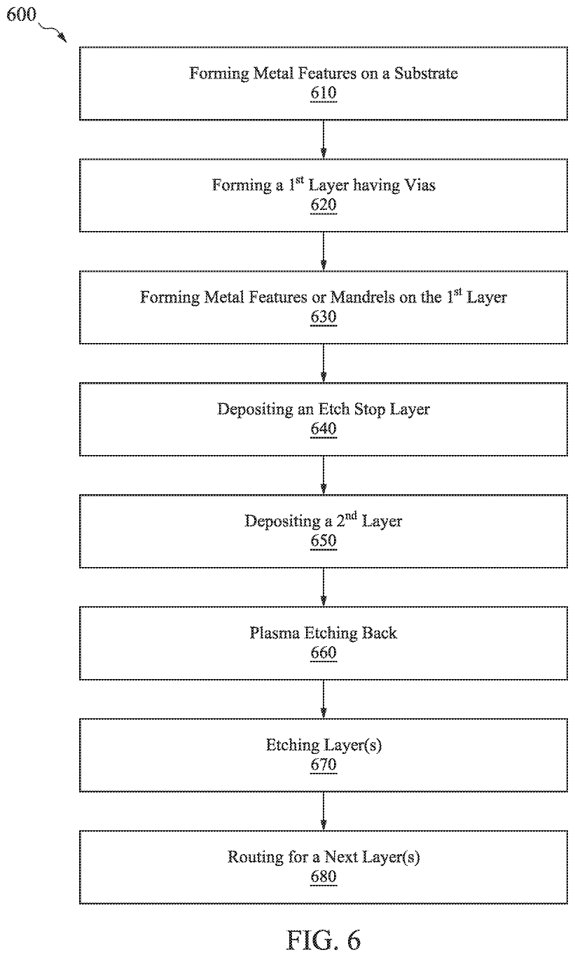

In some embodiments of the present disclosure, FIG. 6 is a flow chart illustrating an improved gap fill method 600. For illustrative purposes, the operations of method 600 will be described with reference to FIGS. 4, 13, and 14. The operations of method 600 can be performed in a different order, repeated (either immediately or further downstream), or not performed depending on specific applications. Further, it is understood that additional operations can be provided before, during, and after method 600, and that other operations may only be briefly described herein.

Referring to FIG. 6, the method 600 begins with operation 610 and the process of forming metal features on a substrate. For example, as shown in FIG. 4, the substrate 410 can have metal features 415 formed thereon. For illustrative purposes, the entire thickness of the substrate 410 is not shown, thus the metal features 415 are formed on a surface or within a subsurface of the substrate 410 and exposed for connection to interlayer interconnects.

In some embodiments, at operation 620, the interlayer interconnects are provided by forming vias 420 in the first layer 425. In some embodiments, at operation 630 and referring to FIGS. 4 and 13, conductive features 1320, corresponding to the conductive features 440 depicted in FIG. 4 (for example, metal features or mandrels), can be formed above the vias 420 to provide electrical connection to the metal features 415 on or within the substrate 410. After forming the conductive features 1320, corresponding to the conductive features 440 depicted in FIG. 4, the method can include, at operation 640 and referring to FIG. 13, depositing an etch stop layer 1310 over the conductive features 1320. The etch stop layer 1310 can be any suitable etch stop material, including oxides, metal oxides, nitrides, metal nitrides, metals, metal alloys, or the like. For example, the etch stop layer can be any one of silicon dioxide, silicon nitride, alumina, titania, zirconia, or the like. In some embodiments, the etch stop layer 1310 can have a thickness ranging from about 300 Å to about 3000 Å (for example, from about 30 nanometers (nm) to about 300 nm). In some embodiments, the etch stop layer 1310 thickness can be about 300 Å, about 400 Å, about 500 Å, about 600 Å, about 700 Å, about 800 Å, about 900 Å, about 1000 Å, about 2000 Å, or about 3000 Å.

After depositing the etch stop layer 1310, the method can include, at operation 650, depositing a material layer 1330 corresponding to the second layer 460 depicted in FIG. 4 over the conductive features 1320 corresponding to the conductive features 440 depicted in FIG. 4 using a plasma enhanced material deposition, for example, plasma enhanced chemical vapor deposition (PECVD), sputtering, plasma enhanced atomic layer deposition (PEALD), or the like. In some embodiments, the material layer 1330 can be a dielectric material. For example, the material layer 1330 can be any one of silicon dioxide, silicon nitride, a polymer (for example, polyimide), or combinations thereof. Referring to FIG. 6, at operation 660, in some embodiments, the plasma enhanced material deposition can be stopped and the plasma can be used to etch back at least a portion of the deposited material layer 1330. As shown in FIG. 13, in some embodiments the plasma etching back operation 660 can provide a film surface profile 1300 having peaks 1340 corresponding to the triangular-shaped peaks 480 depicted in FIG. 4 disposed above the conductive features 1320. In some embodiments, after depositing the material layer 1330, the plasma etching back operation 660 can be performed using an oxygen plasma. In some embodiments, the plasma etching back time can range from about 20 s to about 500 s, the chamber pressure during the plasma etching back can range from about 0.5 mT to about 20 mT, the plasma source RF can range from about 500 W to about 11 kW, and the bias RF can range from about 1 kW to about 100 kW.

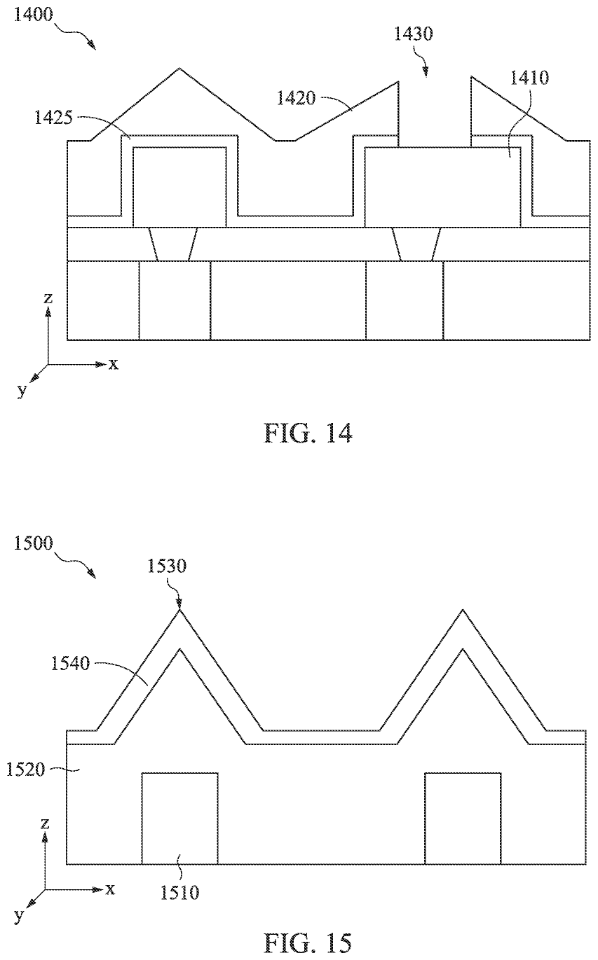

Referring to FIGS. 6, 12, and 14, in some embodiments, the plasma etching back operation 660 can be performed to provide a surface profile 1400 having an exposed conductive feature 1410. As shown in FIG. 14, at least a portion of the material layer 1420 corresponding to the second layer 460 depicted in FIG. 4 and the etch stop layer 1425 can be etched in operation 670 to provide an opening 1430 for an interconnect via. In some embodiments, the next layer routing operation 670 can include metallization (for example, resistive evaporation, sputtering, or electrochemical plating). Referring to FIG. 12, metallization can be performed to provide the interconnect 1210 in the via 1170, corresponding to the interconnect 430 depicted in FIG. 4. Additionally, in some embodiments soldering can be performed to provide a solder bump 1220.

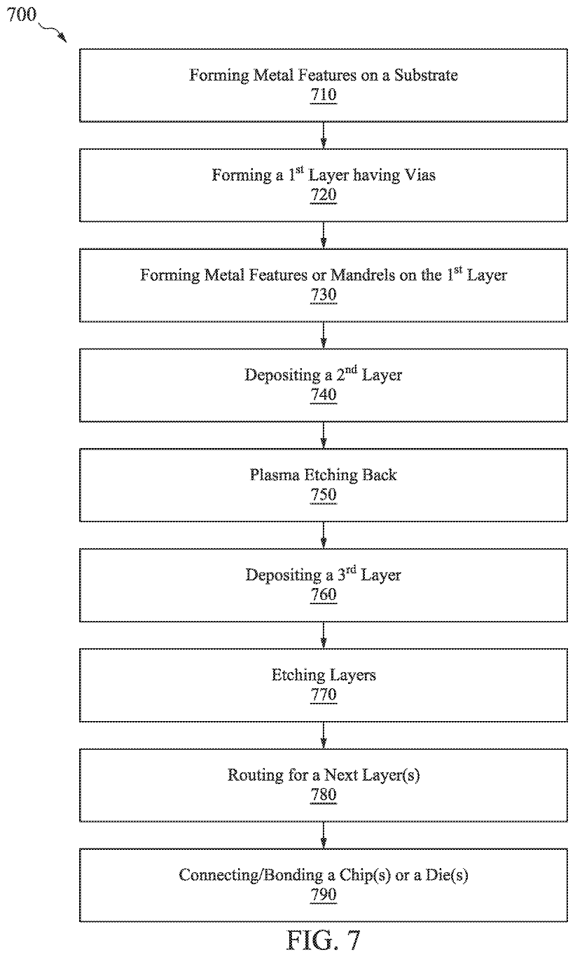

In some embodiments of the present disclosure, FIG. 7 is a flow chart illustrating an improved gap fill method 700. For illustrative purposes, the operations of method 700 will be described with reference to FIGS. 4 and 15-22. The operations of method 700 can be performed in a different order, repeated (either immediately or further downstream), or not performed depending on specific applications. Further, it is understood that additional operations can be provided before, during, and after method 700, and that other operations may only be briefly described herein.

Referring to FIG. 7, the method 700 begins with operation 710 and the process of forming metal features on a substrate. For example, as shown in FIG. 4, the substrate 410 can have metal features 415 formed thereon. For illustrative purposes, the entire thickness of the substrate 410 is not shown, thus the metal features 415 are formed on or within a surface of the substrate 410 and exposed for connection to interlayer interconnects.

In some embodiments, at operation 720, the interlayer interconnects are provided by forming vias 420 in a first layer 425. In some embodiments, at operation 730 and referring to FIGS. 4 and 15, conductive features 1510 corresponding to the conductive features 440 depicted in FIG. 4 can be formed above the vias 420 to provide electrical connection to the metal features 415 on or within the substrate 410. After forming the conductive features 1510, the method can include, at operation 740 and referring to FIG. 15, depositing a second layer 1520 corresponding to the second layer 460 depicted in FIG. 4 over the conductive features 1510 using the plasma enhanced material deposition process, for example, plasma enhanced chemical vapor deposition (PECVD), sputtering, plasma enhanced atomic layer deposition (PEALD), or the like. In some embodiments, the second layer 1520 can be a dielectric material. For example, the second layer 1520 can be any one of silicon dioxide, silicon nitride, a polymer (for example, polyimide), or combinations thereof.

Referring to FIG. 7, at operation 750, in some embodiments, the plasma enhanced material deposition can be stopped and the plasma can be used to etch back at least a portion of the deposited second layer 1520. As shown in FIG. 15, in some embodiments the plasma etching back operation 750 can provide a film surface profile 1500 having peaks 1530 corresponding to the triangular-shaped peaks 480 depicted in FIG. 4 disposed above the conductive features 1510. In some embodiments, after depositing the second layer 1520 corresponding to the second layer 460 depicted in FIG. 4, the plasma etching back operation 750 can be performed using an oxygen plasma. In some embodiments, the plasma etching back time can range from about 20 s to about 500 s, the chamber pressure during the plasma etching back can range from about 0.5 mT to about 20 mT, the plasma source RF can range from about 500 W to about 11 kW, and the bias RF can range from about 1 kW to about 100 kW.

In some embodiments, following the plasma etching back operation 750, a third layer deposition operation 760 can be performed. In some embodiments, at operation 760, the method can include depositing the third layer 1540 corresponding to the third layer 470 depicted in FIG. 4 over the second layer 1520 corresponding to the second layer 460 depicted in FIG. 4 using a plasma enhanced material deposition, for example, plasma enhanced chemical vapor deposition (PECVD), sputtering, plasma enhanced atomic layer deposition (PEALD), or the like. In some embodiments, the third layer 1540 can be a dielectric material. For example, the third layer 1540 can be any one of silicon dioxide, silicon nitride, a polymer (for example, polyimide), or combinations thereof. In some embodiments, the third layer 1540 can have a thickness ranging from about 500 Å to about 5000 Å (for example, from about 50 nanometers (nm) to about 500 nm). In some embodiments, the etch stop layer 1520 thickness can be about 500 Å, about 600 Å, about 700 Å, about 800 Å, about 900 Å, about 1000 Å, about 2000 Å, about 3000 Å, about 4000 Å, or about 5000 Å.

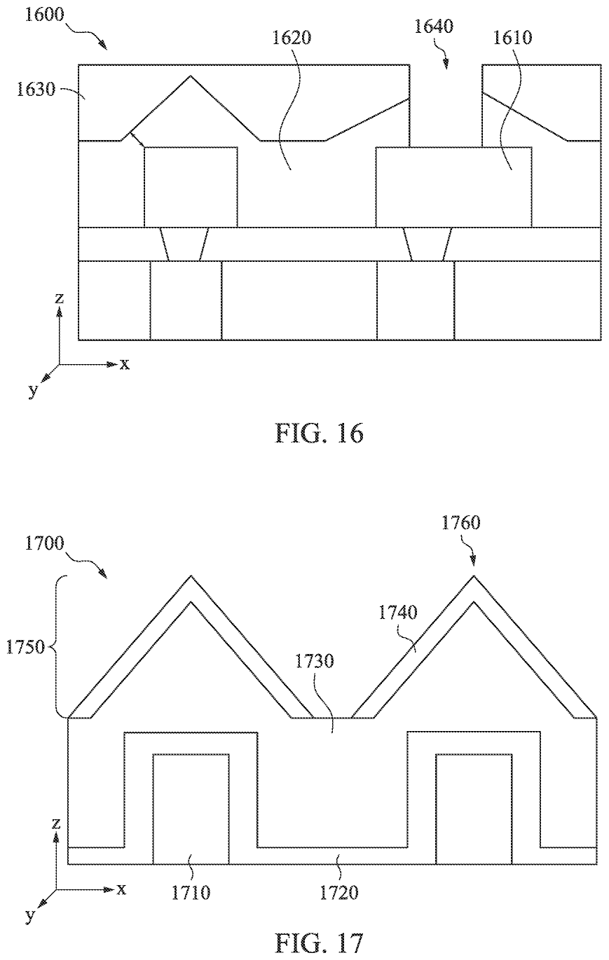

Referring to FIGS. 7, 12, and 16, in some embodiments, after the third layer deposition operation 760 is performed, the semiconductor device can be subjected to processing to provide a surface profile 1600 having an exposed conductive feature 1610 corresponding to the conductive features 440 depicted in FIG. 4. As shown in FIG. 16, at least a portion of the second layer 1620 and the third layer 1630 corresponding to the second layer 460 and the third layer 470 depicted in FIG. 4 can be etched in operation 770 to provide an opening 1640 for an interconnect via. In some embodiments, the next layer routing operation 570 can include metallization (for example, resistive evaporation, sputtering, or electrochemical plating). Referring to FIG. 12, metallization can be performed to provide the interconnect 1210 in the via 1170, corresponding to the interconnect 430 depicted in FIG. 4. Additionally, in some embodiments soldering can be performed to provide a solder bump 1220.

Referring to FIGS. 4, 7, and 17, in some embodiments the method described can include any and/or all of the operations described above. For example, the method can include providing a semiconductor device 1700 that can include the conductive features 1710 corresponding to the conductive features 440 depicted in FIG. 4, the etch stop layer 1720, the second layer 1730, and the third layer 1740, corresponding to the second layer 460 and the third layer 470 depicted in FIG. 4. For example, the method 700 begins with operation 710 and the process of forming metal features on or within a substrate. For example, as shown in FIG. 4, the substrate 410 can have metal features 415 formed thereon or within. For illustrative purposes, the entire thickness of the substrate 410 is not shown, thus the metal features 415 are formed on or within a surface of the substrate 410 and exposed for connection to interlayer interconnects, for example, the interconnect 430 depicted in FIG. 4. In some embodiments, at operation 720, the interlayer interconnects are provided by forming vias 420 in a first layer 425. In some embodiments, at operation 730 and referring to FIGS. 4 and 13, conductive features 1710 corresponding to the conductive features 440 depicted in FIG. 4 can be formed above the vias 420 to provide electrical connection to the metal features 415 on or within the substrate 410. After forming the conductive features 1710 the method can include, forming an etch stop layer 1720 corresponding to operation 640 depicted in FIG. 6 over the conductive features 1710. The etch stop layer 1720 can be any suitable etch stop material, including oxides, metal oxides, nitrides, metal nitrides, metals, metal alloys, or the like. For example, the etch stop layer can be any one of silicon dioxide, silicon nitride, alumina, titania, zirconia, or the like. In some embodiments, the etch stop layer 1720 can have a thickness ranging from about 300 Å to about 3000 Å.

In some embodiments, after forming the etch stop layer 1720, the method can include, at operation 740 and referring to FIG. 17, depositing a second layer 1730 corresponding to the second layer 460 depicted in FIG. 4 over the conductive features 1710 and the etch stop layer 1720 using the plasma enhanced material deposition process noted earlier, for example, plasma enhanced chemical vapor deposition (PECVD), sputtering, plasma enhanced atomic layer deposition (PEALD), or the like In some embodiments, the second layer 1720 can be a dielectric material. For example, the second layer 1720 can be any one of silicon dioxide, silicon nitride, a polymer (for example, polyimide), or combinations thereof.

Referring to FIG. 7, at operation 750, in some embodiments the plasma enhanced material deposition can be stopped and the plasma can be used to etch back at least a portion of the deposited second layer 1730 corresponding to the second layer 460 depicted in FIG. 4. As shown in FIG. 17, in some embodiments the plasma etching back operation 750 can provide a film surface profile 1750 having peaks 1760 corresponding to the triangular-shaped peaks 480 depicted in FIG. 4 disposed above the conductive features 1710 corresponding to the conductive features 440 depicted in FIG. 4. In some embodiments, after depositing the second layer 1730, the plasma etching back operation 750 can be performed using an oxygen plasma. In some embodiments, the plasma etching back time can range from about 20 s to about 500 s, the chamber pressure during the plasma etching back can range from about 0.5 mT to about 20 mT, the plasma source RF can range from about 500 W to about 11 kW, and the bias RF can range from about 1 kW to about 100 kW.

In some embodiments, following the plasma etching back operation 750, a third layer deposition operation 760 can be performed. In some embodiments, at operation 760, the method can include depositing the third layer 1740 over the second layer 1730, corresponding to the second layer 460 and the third layer 470 depicted in FIG. 4, using a plasma enhanced material deposition noted earlier, for example, plasma enhanced chemical vapor deposition (PECVD), sputtering, plasma enhanced atomic layer deposition (PEALD), or the like. In some embodiments, the third layer 1740 can be a dielectric material. For example, the third layer 1740 can be any one of silicon dioxide, silicon nitride, a polymer (for example, polyimide), or combinations thereof. In some embodiments, the third layer 1740 can have a thickness ranging from about 500 Å to about 5000 Å.

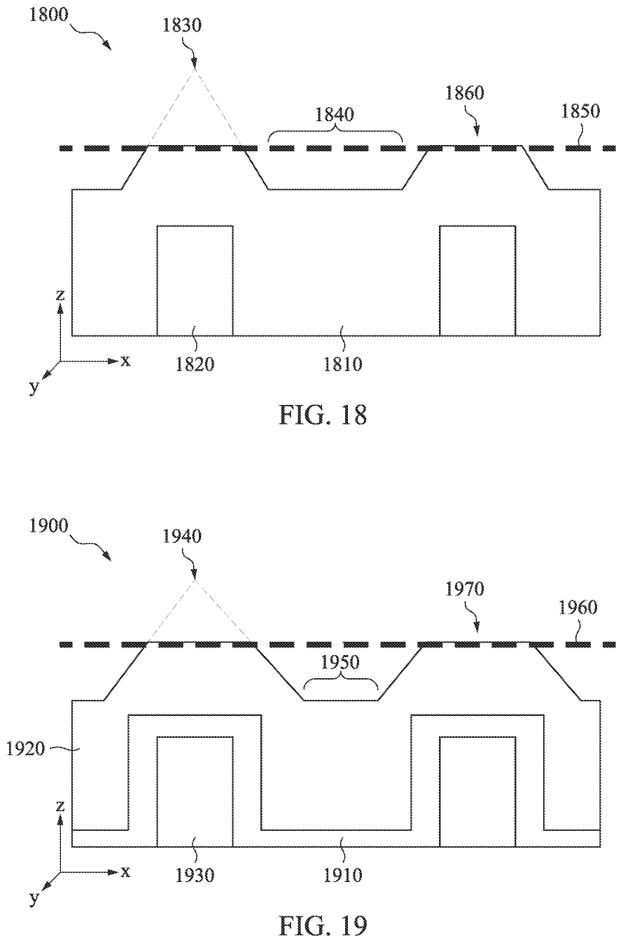

Referring to FIGS. 7, 12, 16, and 17, in some embodiments, after the third layer deposition operation 760 is performed, the semiconductor device can be subjected to processing to provide a surface profile 1600 having an exposed conductive feature (1610, 1710) corresponding to the conductive features 440 depicted in FIG. 4. As shown in FIG. 16, at least a portion of the etch stop layer 1720, the second layer 1730 and the third layer 1740 can be etched in operation 770 to provide an opening, for example the opening 1640 depicted in FIG. 16, for an interconnect via. In some embodiments, the next layer routing operation 780 can include metallization (for example, resistive evaporation, sputtering, or electrochemical plating). Referring to FIG. 12, metallization can be performed to provide the interconnect 1210 in the via 1170, corresponding to the interconnect 430 depicted in FIG. 4. Additionally, in some embodiments soldering can be performed to provide a solder bump 1220. Referring to FIGS. 7 and 18-22, in some embodiments, the method can include a chip and/or die connecting and/or bonding operation 790 to provide the three-dimensional integrated circuit package structure 400 depicted in FIG. 4. In some embodiments, the chip and/or die connecting and/or bonding operation 790 can include a chemical mechanical planarization operation. In some embodiments, chemical mechanical planarization can be a global surface planarizing operation. For example, a top surface of a semiconductor device being manufactured can be planarized in preparation for further downstream processing. In some embodiments, referring to FIG. 18, the second layer 1810 corresponding to the second layer 460 depicted in FIG. 4 deposited over the conductive features 1820 corresponding to the conductive features 440 depicted in FIG. 4 having peaks 1830 and valley regions 1840 corresponding to the triangular-shaped peaks 480 and valley regions 490 depicted in FIG. 4 can be planarized to, for example, reduce the height of the peaks 1830. As shown in FIG. 18, planarization can be performed to any desired amount, for example, to the dashed line 1850. In some embodiments, the planarization operation can provide either a planar surface or a contoured surface having a variable surface topography including plateaus 1860 and valley regions 1840.

In some embodiments, the chip and/or die connecting and/or bonding operation 790 can be applied to a semiconductor device 1900 having an etch stop layer 1910. In some embodiments, referring to FIG. 19, the second layer 1920 corresponding to the second layer 460 depicted in FIG. 4 deposited over the etch stop layer 1910 and the conductive features 1930 corresponding to the conductive features 440 depicted in FIG. 4 having peaks 1940 and valley regions 1950 corresponding to the triangular-shaped peaks 480 and valley regions 490 depicted in FIG. 4 can be planarized to, for example, reduce the height of the peaks 1940. As shown in FIG. 19, planarization can be performed to any desired amount, for example, to the dashed line 1960. In some embodiments, the planarization operation can provide either a planar surface or a contoured surface having a variable surface topography including plateaus 1970 and valley regions 1950.

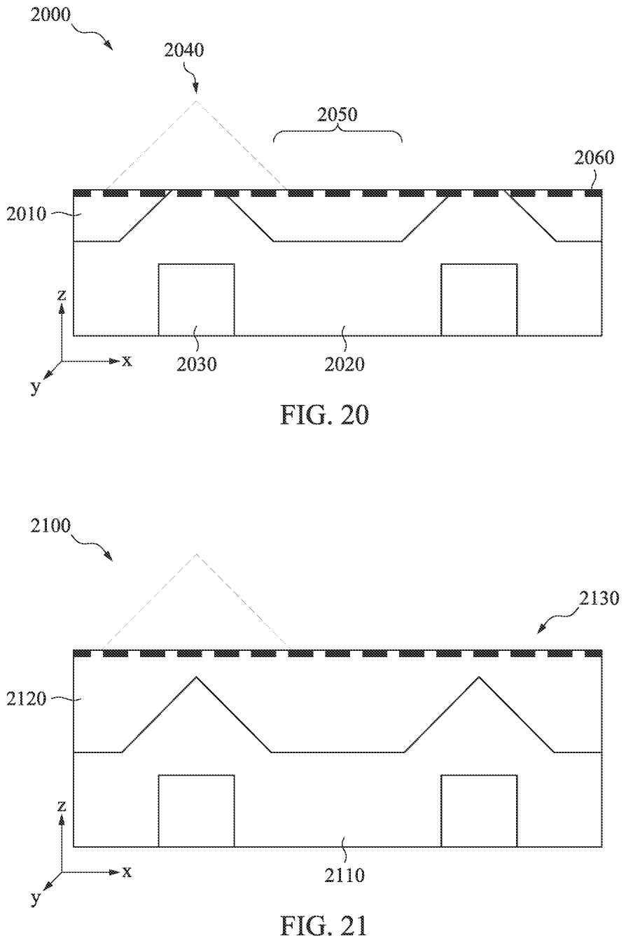

In some embodiments, the chip and/or die connecting and/or bonding operation 790 can be applied to a semiconductor device 2000 having a third layer 2010 corresponding to the third layer 470 depicted in FIG. 4. In some embodiments, referring to FIG. 20, the second layer 2020 corresponding to the second layer 460 depicted in FIG. 4 deposited over the conductive features 2030 corresponding to the conductive features 440 depicted in FIG. 4 having peaks 2040 and valley regions 2050 corresponding to the triangular-shaped peaks 480 and valley regions 490 depicted in FIG. 4 can be planarized to, for example, reduce the height of the peaks 2040 formed by the second layer 2020 and the third layer 2010. As shown in FIG. 20, planarization can be performed to any desired amount, for example, to the dashed line 2060. In some embodiments, the planarization operation can provide a planar surface. In some embodiments, the chemical mechanical planarization operation can expose the second layer 2020 such that the third layer 2010 can be a filler layer within the second layer 2020 valley regions 2050. In some embodiments, referring to FIG. 21, the chemical mechanical planarization can be performed such that the second layer 2110 can remain obscured by the third layer 2120, for example, at a point 2130.

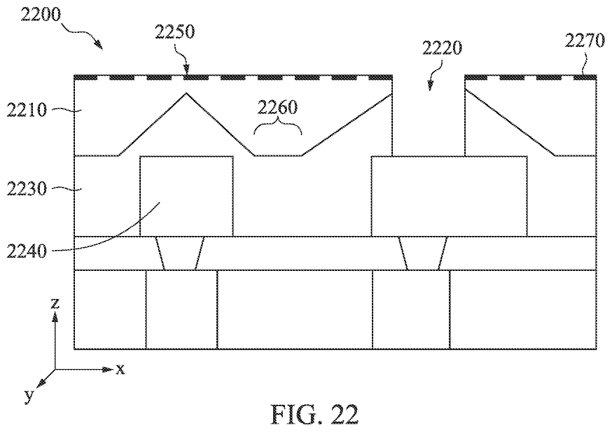

In some embodiments, the chip and/or die connecting and/or bonding operation 790 can be applied to a semiconductor device 2200 having a third layer 2210 and a via 2220 etched through the third layer 2210 and the second layer 2230. In some embodiments, referring to FIG. 22, the second layer 2230 deposited over the conductive features 2240 having peaks 2250 and valley regions 2260 can be planarized to, for example, provide a planar surface of the third layer 2210. As shown in FIG. 22, planarization can be performed to any desired amount, for example, to the dashed line 2270. The chip and/or die connecting and/or bonding operation 790 can be performed to provide the three dimensional integrated circuit package structure 400 depicted in FIG. 4 using solder, braze, wire bonding, epoxy, or the like.

In some embodiments, a semiconductor structure can include conductive features disposed on a first layer and a second layer disposed over the conductive features and the first layer. In some embodiments, the second layer can include a first triangular-shaped peak above a first conductive feature, a second triangular-shaped peak above a second conductive feature, and a valley region between the first and second triangular-shaped peaks. In some embodiments, the valley region can have a height above the first layer that is less than the height of the first and second triangular-shaped peaks above the first layer.

In some embodiments, a semiconductor device can include conductive features on a first layer having a height above the first layer and a distance between each of the conductive features and a second layer over the conductive features and the first layer. In some embodiments, the second layer can have a first height above the conductive features and a second height above the first layer. In some embodiments, the second layer includes a first triangular-shaped peak above a first conductive feature, a second triangular-shaped peak above a second conductive feature, and a valley region between the first and second triangular-shaped peaks. In some embodiments, a peak-to-peak distance between the first triangular-shaped peak and the second triangular-shaped peak is greater than the distance between the first conductive feature and the second conductive feature. In some embodiments, the valley region height above the first layer that is greater than the height of each of the conductive features.

In some embodiments, a method includes forming conductive features on a first layer, depositing a second layer over the conductive features and the first layer, and etching at least a portion of the second layer. In some embodiments, etching includes forming a first triangular-shaped peak above a first conductive feature, a second triangular-shaped peak above a second conductive feature, and a valley region between the first and second triangular-shaped peaks. In some embodiments, the valley region can be formed having a height above the first layer that is less than a height of the triangular-shaped peaks above the first layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a plurality of conductive features disposed on a first layer; and
a second layer disposed over the plurality of conductive features and the first layer,
wherein the second layer comprises a first triangular-shaped peak corresponding to a first conductive feature, a second triangular-shaped peak corresponding to a second conductive feature, and a valley region between the first and second triangular-shaped peaks, wherein the valley region comprises a height above the first layer that is less than a height of the first and second triangular-shaped peaks above the first layer.

2. The structure of claim 1, wherein the first layer comprises a substrate, a conductive layer, a dielectric layer, an interconnect, or combinations thereof.

3. The structure of claim 1, wherein each conductive feature in the plurality of conductive features comprises a metal or a mandrel.

4. The structure of claim 1, wherein a distance between each conductive feature in the plurality of conductive features ranges from about 1 micron to about 5 microns.

5. The structure of claim 1, wherein the second layer and the first layer comprise an etch stop layer, a dielectric layer, a polymer layer, or combinations thereof.

6. The structure of claim 1, wherein a height of the triangular-shaped peaks above each conductive feature is substantially equal to a height of the valley regions above the first layer.

7. The structure of claim 6, wherein the height of the valley regions above the first layer is greater than a height of each conductive feature.

8. The structure of claim 1, wherein a top surface of the valley region in the second layer is substantially flat.

9. The structure of claim 8, wherein the second layer comprises an angle between the top surface of the valley region and the triangular-shaped peaks ranging from about 90° to about 150°.

10. A semiconductor device, comprising:
a plurality of conductive features on a first layer having a height above the first layer and a distance between each conductive feature in the plurality of conductive features;
a second layer over the plurality of conductive features and the first layer, the second layer comprising a first height above the conductive features and a second height above the first layer,
wherein the second layer comprises a first triangular-shaped peak above a first conductive feature, a second triangular-shaped peak above a second conductive feature, and a valley region between the first and second triangular-shaped peaks, wherein a peak-to-peak distance between the first triangular-shaped peak and the second triangular-shaped peak is greater than the distance between the first conductive feature and the second conductive feature.

11. The semiconductor device of claim 10, wherein the second layer comprises a valley region disposed above the first layer between the first triangular-shaped peak above the first conductive feature and the second triangular-shaped peak above the second conductive feature, and
wherein the second layer comprises a valley region height above the first layer that is greater than the height of each conductive feature in the plurality of conductive features.

12. The semiconductor device of claim 10, wherein each conductive feature in the plurality of conductive features is a metal interconnect, a mandrel, or combinations thereof, and the second layer comprises an etch stop layer, a dielectric layer, a polymer layer, or combinations thereof.

13. The semiconductor device of claim 10, wherein the second layer and the first layer are substantially flat.

14. The semiconductor device of claim 10, wherein the second layer comprises a via exposing a top of at least one conductive feature in the plurality of conductive features.

15. A method, comprising:
forming a plurality of conductive features on a first layer;
depositing a second layer over the plurality of conductive features and the first layer; and
etching at least a portion of the second layer,
wherein the etching comprises forming a first triangular-shaped peak above a first conductive feature, a second triangular-shaped peak above a second conductive feature, and a valley region between the first and second triangular-shaped peaks, wherein the valley region is formed having a height above the first layer that is less than a height of the first and second triangular-shaped peaks above the first layer.

16. The method of claim 15, wherein forming the plurality of conductive features comprises forming each conductive feature in the plurality of conductive features above an interconnect or above a dielectric layer.

17. The method of claim 15, wherein depositing the layer over the plurality of conductive features and the first layer comprises covering each conductive feature in the plurality of conductive features with a dielectric material, a polymer material, an etch stop material, or combinations thereof

18. The method of claim 15, wherein depositing the second layer over the plurality of conductive features and the first layer comprises depositing the second layer using a plasma enhanced material deposition process.

19. The method of claim 18, wherein etching at least the portion of the second layer comprises etching at least the portion of the second layer with a plasma etch.

20. The method of claim 15, further comprising planarizing the second layer and the first layer.
